(19) United States
(12) Patent Application Publication
(10) Pub. No.: US 2025/0225301 A1
(43) Pub. Date: Jul. 10, 2025

(54) METHOD FOR PERFORMING BLOCK LEVEL EXPLORATION OF INTEGRATED CIRCUIT DESIGN, ASSOCIATED ELECTRONIC DEVICE AND ASSOCIATED COMPUTER-READABLE MEDIUM

(71) Applicant: MEDIATEK INC., Hsin-Chu (TW)

(72) Inventors: Sheng-Chuan Yen, Hsinchu City (TW); Chen-Hsing Lo, Hsinchu City (TW); Long-Feng Chen, Hsinchu City (TW); Shen-Li Lo, Hsinchu City (TW); Bo-Heng Yu, Hsinchu City (TW); Tai-Ting Chen, Hsinchu City (TW); Ming-Fang Tsai, Hsinchu City (TW); Chun-Chih Yang, Hsinchu City (TW); Hang-Kaung Shu, Hsinchu City (TW)

(73) Assignee: MEDIATEK INC., Hsin-chu (TW)

(21) Appl. No.: 18/407,480

(22) Filed: Jan. 9, 2024

(51) Int. Cl. G06F 30/327

(52) U.S. Cl. CPC G06F 30/327

(57) ABSTRACT

A method for performing block level exploration of integrated circuit (IC) design and associated electronic device and computer-readable medium are provided. The method may include running a synthesis control procedure on at least one processor within the electronic device, for performing automatic placement and routing of a target design of an IC. The synthesis control procedure may include: performing netlist generation to generate a first netlist for the target design of the IC; performing performance, power and area (PPA) configurations preparation to prepare a set of PPA-related configurations; performing macro placement generation to generate a set of macro placements corresponding to the set of PPA-related configurations; and executing synthesis processing according to the set of macro placements to generate multiple intermediate netlists, respectively, and generating multiple synthesis reports of the multiple intermediate netlists for the set of PPA-related configurations, respectively, for selectively outputting intermediate netlist as resultant netlist and floorplan.

### BACKGROUND

The present invention is related to integrated circuit (IC) design, and more particularly, to a method for performing block level exploration of IC design, and an associated electronic device and an associated computer-readable medium.

According to the related art, the work of the IC design of an IC product may be done by multiple engineers belonging to different IC design teams in order to enhance the efficiency. Some problems may occur, however. For example, a first team may focus on early design, and a second team may focus on placement and routing. When there is a manpower bottleneck of the second team, a first engineer in the first team may have no chance to discuss with any engineer in the second team during an early design phase due to the manpower bottleneck of the second team. If nobody of the second team is able to get involved with the project of the IC product in the early design phase, the first engineer may work hard on the early design of the IC product without considering physical location information, and some issues of the IC product may not be found earlier, causing the time to market (e.g., the total time it takes to design and manufacture the IC product before the IC product is available to buy) to become longer. Thus, a novel method and associated architecture are needed for solving the problems without introducing any side effect or in a way that is less likely to introduce a side effect.

### SUMMARY

It is an objective of the present invention to provide a method for performing block level exploration of IC design, and an associated electronic device and an associated computer-readable medium, in order to solve the above-mentioned problems.

At least one embodiment of the present invention provides a method for performing block level exploration of IC design, where the method is applicable to an electronic device. The method may comprise running a synthesis control procedure on at least one processor within the electronic device, for performing automatic synthesis plus place and route (ASPR) of a target design of an IC. For example, the synthesis control procedure may comprise: performing netlist generation to generate a first netlist for the target design of the IC; performing performance, power and area (PPA) configurations preparation to prepare a set of PPA-related configurations; performing macro placement generation to generate a set of macro placements corresponding to the set of PPA-related configurations; and executing synthesis processing according to the set of macro placements to generate multiple intermediate netlists, respectively, and generating multiple synthesis reports of the multiple intermediate netlists for the set of PPA-related configurations, respectively, for selectively outputting at least one intermediate netlist among the multiple intermediate netlists as at least one resultant netlist and at least one floor plan (or floor-plan/floorplan), for use of further place and route (P&R) processing.

According to some embodiments, the present invention also provides the electronic device that operates according to the method mentioned above, where the electronic device may be arranged to selectively output the aforementioned at least one intermediate netlist among the multiple intermediate netlists as the aforementioned at least one resultant netlist, for use of further P&R processing.

According to some embodiments, the present invention also provides a computer-readable medium storing a program code related to the method mentioned above. For example, when executed by the aforementioned at least one processor, the program code may cause the electronic device to operate according to the method mentioned above.

It is an advantage of the present invention that the present invention method and the associated apparatus such as the electronic device operating according to the method can integrate a part of work regarding placing and routing into the early design of an IC product to allow some issues of the IC product to be found earlier, in order to prevent any delay of the project of the IC product, and more particularly, achieve a shorter time to market. In addition, the present invention method and the associated apparatus such as the electronic device operating according to the method can greatly decrease the probability of redoing the iterations of reconfiguring synthesis settings and restarting P&R operations, and therefore prevent the associated costs from being increased. Additionally, the present invention method and the associated apparatus can solve the problems of the related art without introducing any side effect or in a way that is less likely to introduce a side effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates, in the lower half part thereof, an ASPR control scheme of a method for performing block level exploration of IC design according to an embodiment of the present invention, where a non-ASPR control scheme may be illustrated in the upper half part of FIG. 1 for better comprehension.

FIG. 2 illustrates a working flow of a synthesis control procedure corresponding to the ASPR control scheme shown in FIG. 1 according to an embodiment of the present invention.

FIG. 3 illustrates a loop-based control scheme of the method according to an embodiment of the present invention.

FIG. 4 illustrates a working flow of the synthesis control procedure corresponding to the ASPR control scheme shown in FIG. 1 according to another embodiment of the present invention.

FIG. 5 illustrates some implementation details regarding the area exploration and the performance exploration of the loop-based control scheme shown in FIG. 3 according to an embodiment of the present invention.

FIG. 6 illustrates some implementation details regarding the power exploration of the loop-based control scheme shown in FIG. 3 according to an embodiment of the present invention.

FIG. 7 illustrates, in the right half part thereof, an ASPR-based power estimation control scheme of the method according to an embodiment of the present invention, where a non-ASPR-based power estimation control scheme may be illustrated in the left half part of FIG. 7 for better comprehension.

FIG. 8 illustrates an electronic device that operates according to the method according to an embodiment of the present invention, where a computer-readable medium storing a program code related to the method may be illustrated in the lower left part of FIG. 8 for better comprehension.

### DETAILED DESCRIPTION

Certain terms are used throughout the following description and claims, which refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

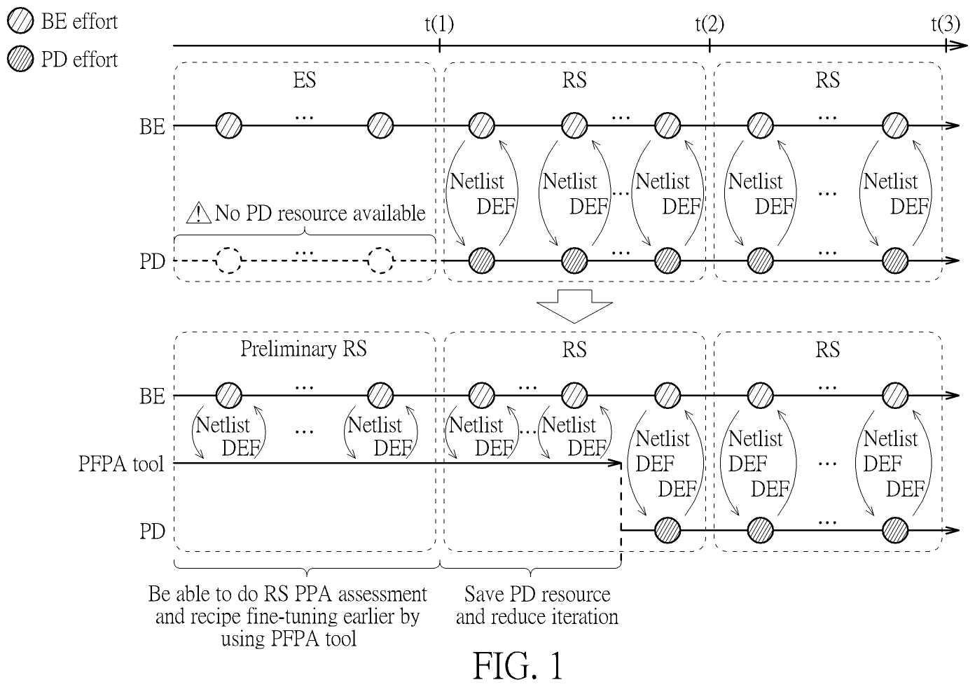

FIG. 1 illustrates, in the lower half part thereof, an ASPR control scheme of a method for performing block level exploration of IC design according to an embodiment of the present invention, where a non-ASPR control scheme may be illustrated in the upper half part of FIG. 1 for better comprehension. The horizontal axis may represent time. During IC design of an IC product (e.g., an IC), engineers of multiple IC design teams may focus on their own works in multiple design phases. For example, the multiple design phases may comprise an initial design phase, an early design phase coming after the initial design phase before the time point t(1), a first design phase between the time points t(1) and t(2), and a second design phase between the time points t(2) and t(3), and the multiple IC design teams may comprise a backend (BE) integrator team and a physical designer (PD) team, but the present invention is not limited thereto. In the initial design phase, a designer (DE) engineer may write a register transfer level (RTL) code (e.g., Verilog code) according to the specification of the IC product, for being used in the early design phase. According to some viewpoints, the time point t(1) may represent the beginning time point of the first design phase, the time point t(2) may represent the beginning time point of the second design phase, and the time point t(3) may represent a time point of the completion of the BE tasks (or the completion of the last version of the netlist) without further change of the netlist regarding the design data of the IC product, but the present invention is not limited thereto.

According to the non-ASPR control scheme shown in the upper half part of FIG. 1, a backend integrator (labeled “BE” for brevity) may take over the RTL code and do early synthesis (ES) such as the synthesis without using any physical component location (e.g., any physical SRAM location) as any input until the time point t(1). In the subsequent phases such as the first and the second design phases, starting from the time point t(1), the backend integrator may output a netlist for listing the components of the IC design, and a physical designer (labeled “PD” for brevity) may take over the netlist and start P&R operations to do component placement of the components (e.g., SRAM) manually, in order to output a design exchange format (DEF) file (labeled “DEF” for brevity) for indicating the respective locations of the components within the IC design. For example, if some issues are found, the backend integrator may do real synthesis (RS) such as the synthesis using the physical component locations (e.g., the physical SRAM locations) in the DEF file as inputs, in order to update the netlist, and the physical designer may take over the updated netlist to restart P&R operations to do component placement such as SRAM placement, etc. manually according to the updated netlist in order to generate the updated DEF file. There may be multiple iterations of reconfiguring synthesis settings and restarting P&R operations in the first design phase and the second design phase. Please note that the backend integrator may have no chance to discuss with any engineer in the physical designer team during the early design phase before the time point t(1) due to the manpower bottleneck of the physical designer team (labeled “No PD resource available” for brevity). In this situation, the backend integrator may work hard on the early synthesis of the IC product without considering physical location information, and some issues of the IC product may not be found earlier. For example, the backend integrator and the physical designer may not be able to explore sufficient PPA-related configurations (e.g., the PPA-related configurations for synthesis and the placement and routing) efficiently as early as possible. As a result, the multiple IC design teams may only compromise on manpower and schedule and try a few settings, and then the project may just continue with one of the few settings that is merely usable. Under a worst-case scenario, the PPA-related configurations may have been set incorrectly, resulting in the need to restart most of the whole work, including the early synthesis as well as the subsequent processing such as the iterations of reconfiguring synthesis settings and restarting P&R operations, and even the need of changing the design (or the Verilog code), which may be very labor intensive and may require huge time costs.

Because of the limited time and engineering resources, it is hard to explore comprehensive PPA-related configurations in an early stage of an IC design flow. Incorrect PPA-related configurations would lead to serious problems and need to revisit from synthesis settings and restart the place and routing process. It would significantly affect the schedule and waste lots of resources such as computing resources, human resources, licenses, etc. For example, inaccurate area sizing may cause a heavy workload regarding the synthesis and P&R processing. More particularly, an insufficient design area can result in congestion issues, necessitating a greater number of iterations and significant engineering resources to reconfigure synthesis settings and restart automatic place and route (APR) operations. Conversely, an excessively large design area can result in wasteful manufacturing costs. In addition, improper power grid density settings can lead to severe leakage or congestion issues or area wastage at excessively higher power density settings. Additionally, incorrect frequency settings can lead to timing issues and necessitate restarting the APR work.

According to the ASPR control scheme shown in the lower half part of FIG. 1, the backend integrator (labeled “BE” for brevity) may take over the RTL code and do preliminary real synthesis (labeled “Preliminary RS” for brevity) with the aid of a physical floorplan placement automation (PFPA) tool in order to generate and output a netlist for listing the components of the IC design. In a situation where no engineer in the physical designer team has been assigned to help the backend integrator during the early design phase before the time point t(1) due to the manpower bottleneck of the physical designer team, the PFPA tool may interact with the backend integrator, and therefore may be regarded as a pseudo physical designer according to some viewpoints, but the present invention is not limited thereto. The backend integrator may output a netlist for listing the components of the IC design, and the PFPA tool may take over the netlist and start P&R operations to automatically perform component placement of the components (e.g., SRAM), in order to output a DEF file (labeled “DEF” for brevity) for indicating the respective locations of the components within the IC design. For example, if some issues are found, the backend integrator may do the preliminary real synthesis (RS) such as the synthesis using the physical component locations (e.g., the physical SRAM locations) in the DEF file as inputs, in order to update the netlist, and the PFPA tool may take over the updated netlist to restart P&R operations to automatically perform component placement (e.g., SRAM placement) according to the updated netlist in order to generate the updated DEF file. There may be multiple iterations of reconfiguring synthesis settings and restarting P&R operations in the early design phase before the time point t(1), and this may continue in at least one portion of the first design phase after the time point t(1).

In the first design phase, the backend integrator may do the preliminary real synthesis and the real synthesis (labeled “RS” for brevity), and more particularly, output a netlist for listing the components of the IC design, as well as an automatically generated DEF file such as the DEF file generated by the PFPA tool (labeled “Netlist DEF” for brevity), and the physical designer (labeled “PD” for brevity) may take over the netlist and the automatically generated DEF file and start P&R operations to do component placement of the components (e.g., SRAM) manually in order to output a manually generated DEF file such as the DEF file generated by the physical designer (labeled “DEF” for brevity), for being returned to the backend integrator. For example, if some issues are found, the backend integrator may do the real synthesis (RS) such as the synthesis using the physical component locations (e.g., the physical SRAM locations) in the manually generated DEF file as inputs, in order to update the netlist and the automatically generated DEF file, and the physical designer may take over the updated netlist and the updated automatically generated DEF file to restart P&R operations according to the updated netlist and the updated automatically generated DEF file. There may be only an iteration of reconfiguring synthesis settings and restarting P&R operations in the first design phase and one or more subsequent iterations of reconfiguring synthesis settings and restarting P&R operations in the second design phase. Please note that the backend integrator may be able to do real RS PPA assessment and recipe fine-tuning earlier by using the PFPA tool, allowing efficient exploration and assessment of PPA-related configurations in synthesis and APR for IC design. Additionally, the ASPR control scheme can save PD resource and reduce the number of iterations.

According to some embodiments, a computer-readable medium may be arranged to store a program code related to the method mentioned above, where the PFPA tool may be implemented by way of the program code running on at least one processor within an electronic device that operates according to the method. Under control of the program code running on the aforementioned at least one processor, the electronic device can perform the block level exploration of IC design.

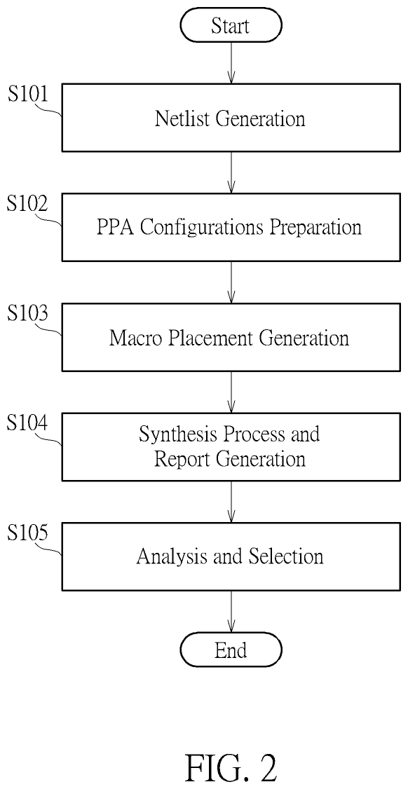

FIG. 2 illustrates a working flow of a synthesis control procedure (e.g., the PFPA tool) corresponding to the ASPR control scheme shown in FIG. 1 according to an embodiment of the present invention. The synthesis control procedure such as the PFPA tool may be implemented by way of the program code mentioned above. For example, when executed by the aforementioned at least one processor, the program code may cause the electronic device to operate according to the method mentioned above. Under control of the synthesis control procedure (e.g., the PFPA tool) running on the aforementioned at least one processor, the electronic device may perform the operations of Steps S101-S105, for performing ASPR of a target design of the IC product (e.g., the IC).

In Step S101, the electronic device may perform netlist generation to generate a first netlist (e.g., an initial netlist) for the target design of the IC. More particularly, the electronic device may execute synthesis processing without referring to any predetermined physical location information regarding any part of the IC, to generate the first netlist for the target design of the IC. For example, the electronic device may execute the synthesis processing by executing a synthesis processing subroutine, but the present invention is not limited thereto. In addition, during performing the netlist generation to generate the first netlist for the target design of the IC, the electronic device may receive an RTL code of the IC, such as the aforementioned RTL code written by the designer (DE) engineer, where the RTL code may indicate the target design of the IC. Additionally, during performing the netlist generation to generate the first netlist for the target design of the IC, the electronic device may execute the synthesis processing according to the RTL code to generate the first netlist for the target design of the IC.

In Step S102, the electronic device may perform PPA configurations preparation to prepare a set of PPA-related configurations (e.g., a set of different shapes and area sizes for the target design). For better comprehension, the set of PPA-related configurations may comprise at least one performance-related configuration, at least one power-related configuration and at least one area-related configuration. For example, the aforementioned at least one area-related configuration may comprise at least one configuration of at least one area for being occupied by at least one predetermined component (e.g., at least one static random access memory (SRAM) and/or at least one power grid) within the IC, and more particularly, may further comprise at least one configuration of one or a combination of a port location of at least one port within the IC, a feedthrough port number of at least one feedthrough port within the IC, a feedthrough port location of the aforementioned at least one feedthrough port, at least one routing layer within the IC, and a user-defined region for at least one module within the IC, where the aforementioned at least one configuration of the aforementioned at least one area may comprise at least one configuration of one or a combination of a shape of the aforementioned at least one area, an area size of the aforementioned at least one area, and an aspect ratio of the aforementioned at least one area, but the present invention is not limited thereto. In some examples, the aforementioned at least one area-related configuration may comprise the respective configurations of the aforementioned at least one area, the port location, the feedthrough port number, the feedthrough port location, the aforementioned at least one routing layer, and the user-defined region.

In addition, the aforementioned at least one performance-related configuration may also comprise the aforementioned at least one configuration of the aforementioned at least one area for being occupied by the aforementioned at least one predetermined component within the IC, and more particularly, may further comprise at least one configuration of one or a combination of the port location of the aforementioned at least one port within the IC, the feedthrough port number of the aforementioned at least one feedthrough port within the IC, the feedthrough port location of the aforementioned at least one feedthrough port, the aforementioned at least one routing layer within the IC, and the user-defined region for the aforementioned at least one module within the IC, where the aforementioned at least one configuration of the aforementioned at least one area may comprise the aforementioned at least one configuration of the one or the combination of the shape of the aforementioned at least one area, the area size of the aforementioned at least one area, and the aspect ratio of the aforementioned at least one area, but the present invention is not limited thereto. In some examples, the aforementioned at least one performance-related configuration may comprise the respective configurations of the aforementioned at least one area, the port location of the aforementioned at least one port within the IC, the feedthrough port number of the aforementioned at least one feedthrough port within the IC, the feedthrough port location of the aforementioned at least one feedthrough port, the aforementioned at least one routing layer within the IC, and the user-defined region for the aforementioned at least one module within the IC.

Additionally, the aforementioned at least one power-related configuration may also comprise the aforementioned at least one configuration of the aforementioned at least one area for being occupied by the aforementioned at least one predetermined component within the IC, and more particularly, may further comprise at least one configuration of one or a combination of the port location of the aforementioned at least one port within the IC, and a power grid setting of at least one power grid line within the IC, where the aforementioned at least one configuration of the aforementioned at least one area may comprise the aforementioned at least one configuration of the one or the combination of the shape of the aforementioned at least one area, the area size of the aforementioned at least one area, and the aspect ratio of the aforementioned at least one area, but the present invention is not limited thereto. In some examples, the aforementioned at least one power-related configuration may comprise the respective configurations of the aforementioned at least one area, the port location, and the power grid setting.

In Step S103, the electronic device may perform macro placement generation (e.g., macro locations generation) to generate a set of macro placements (e.g., a set of macro locations, such as the macro locations of multiple macro circuits such as multiple SRAMs, etc.) corresponding to the set of PPA-related configurations, for automatically performing the component placement (e.g., the SRAM placement) mentioned above, but the present invention is not limited thereto. For example, the electronic device may generate more than one set of macro placements such as multiple sets of macro placements (e.g., multiple sets of macro locations, such as different versions of the macro locations of the multiple macro circuits) respectively corresponding to the set of PPA-related configurations, for being used in the associated steps of the synthesis control procedure (e.g., the PFPA tool), for automatically performing the component placement (e.g., the SRAM placement) mentioned above according to different sets of macro placements (e.g., the multiple sets of macro placements), respectively. In addition, in a situation where the set of PPA-related configurations comprise the aforementioned at least one configuration of the aforementioned at least one area for being occupied by the aforementioned at least one predetermined component within the IC, the electronic device may perform the macro placement generation to generate the set of macro placements corresponding to the set of PPA-related configurations for placing the aforementioned at least one predetermined component, where the aforementioned at least one configuration of the aforementioned at least one area may comprise the aforementioned at least one configuration of the one or the combination of the shape of the aforementioned at least one area, the area size of the aforementioned at least one area, and the aspect ratio of the aforementioned at least one area, but the present invention is not limited thereto.

In Step S104, the electronic device may execute synthesis processing according to the set of macro placements (e.g., the set of macro locations) to generate multiple intermediate netlists, respectively, and generate multiple synthesis reports of the multiple intermediate netlists for the set of PPA-related configurations, respectively (labeled “Synthesis Process and Report Generation” for brevity), for selectively outputting at least one intermediate netlist among the multiple intermediate netlists as at least one resultant netlist, for use of further P&R processing.

In Step S105, the electronic device may perform analysis and selection, and more particularly, analyze the multiple synthesis reports of the multiple intermediate netlists according to at least one predetermined rule (e.g., one or more predetermined rules) in order to selectively output the aforementioned at least one intermediate netlist among the multiple intermediate netlists as the aforementioned at least one resultant netlist, and output the automatically generated DEF file, for use of further P&R processing, where the automatically generated DEF file may comprise good macro placements (e.g., good macro locations among the macro locations of the multiple macro circuits) such as good SRAM placements/locations, etc., but the present invention is not limited thereto. For example, the electronic device may analyze the multiple synthesis reports of the multiple intermediate netlists according to the aforementioned at least one predetermined rule to determine at least one PPA-related configuration (e.g., the PPA-related configuration(s) conforming to the aforementioned at least one predetermined rule) among the set of PPA-related configurations to be at least one optimized PPA-related configuration, select the aforementioned at least one intermediate netlist corresponding to the aforementioned at least one optimized PPA-related configuration from the multiple intermediate netlists, and output the aforementioned at least one intermediate netlist as the aforementioned at least one resultant netlist, for use of further P&R processing, but the present invention is not limited thereto. According to some embodiments, the electronic device may output the aforementioned at least one resultant netlist and the associated macro placements (e.g., the associated floorplans), for being delivered to the physical designer for further P&R processing.

For better comprehension, the synthesis control procedure may be illustrated with the working flow shown in FIG. 2, but the present invention is not limited thereto. According to some embodiments, one or more steps may be added, deleted, or changed in the working flow shown in FIG. 2. For example, the electronic device may run the synthesis control procedure on the aforementioned at least one processor within the electronic device to selectively re-execute at least one partial working flow (e.g., one or more partial working flows) within the working flow shown in FIG. 2, such as the partial working flow comprising Steps S102-S104 and/or the partial working flow comprising Steps S101-S104, for performing the ASPR of the target design of the IC product (e.g., the IC). For brevity, similar descriptions for these embodiments are not repeated in detail here.

In the embodiments described above, the aforementioned at least one configuration of the aforementioned at least one area may comprise the aforementioned at least one configuration of the one or the combination of the shape of the aforementioned at least one area, the area size of the aforementioned at least one area, and the aspect ratio of the aforementioned at least one area, but the present invention is not limited thereto. According to some embodiments, the aforementioned at least one configuration of the aforementioned at least one area may comprise a set of candidate shapes of the aforementioned at least one area, a set of candidate area sizes of the aforementioned at least one area, and a set of candidate aspect ratio of the aforementioned at least one area, for implementing the aforementioned at least one predetermined component within the IC. For brevity, similar descriptions for these embodiments are not repeated in detail here.

According to some embodiments, the electronic device may execute the synthesis process without physical location information to generate the first netlist for the target design in Step S101, prepare the set of PPA-related configurations such as the set of different shapes and area sizes for the target design in Step S102, execute one or more automatic macro placement processes to generate at least one macro placement for each PPA-related configuration among the set of PPA-related configurations in Step S103, execute the synthesis process on each generated macro placement to generate the multiple intermediate netlists and the multiple synthesis reports for all PPA-related configurations among the set of PPA-related configurations in Step S104, and analyze the multiple synthesis reports to choose one or more netlists and one or more macro placements corresponding to one or more pre-selected PPA-related configurations (e.g., one or more optimized PPA-related configurations) that exhibit the best PPA-related settings in Step S105, for further P&R processing. For brevity, similar descriptions for these embodiments are not repeated in detail here.

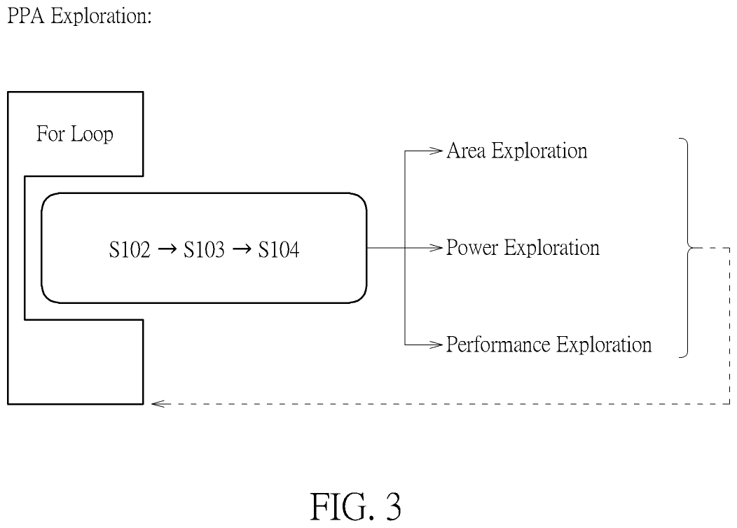

FIG. 3 illustrates a loop-based control scheme of the method according to an embodiment of the present invention. The PPA exploration in the loop-based control scheme may comprise area exploration, power exploration and performance exploration, and the electronic device may perform the PPA exploration (e.g., the area exploration, the power exploration and the performance exploration) according to multiple predetermined rules (e.g., the predetermined rules respectively corresponding to the area exploration, the power exploration and the performance exploration), where the multiple predetermined rules may be taken as an example of the aforementioned at least one predetermined rule. More particularly, the multiple predetermined rules may comprise:

(1) a first predetermined rule corresponding to the area exploration: multiple first factors (e.g., multiple parameters, multiple indexes, and/or multiple estimation results) regarding the area exploration in the multiple synthesis reports should fall within predetermined ranges of the multiple first factors, respectively, for example, the multiple first factors may comprise a target standard cell utilization rate (U-rate), one or more timing estimation results, one or more delay estimation results, a congestion hotspot score, a congestion overflow ratio, one or more cell threshold voltage (VT) usage rates (or ratios) and a cell area;

(2) a second predetermined rule corresponding to the power exploration: multiple second factors (e.g., multiple parameters, multiple indexes, and/or multiple estimation results) regarding the power exploration in the multiple synthesis reports should fall within predetermined ranges of the multiple second factors, respectively, for example, the multiple second factors may comprise one or more power estimation results, one or more glitch estimation results, a difference between a predicted power of the IC and a target power of the IC, a leakage power and a dynamic power of the IC, at least one VT cell usage ratio of the IC, such as a low VT (LVT) cells usage ratio, a standard VT (SVT) cells usage ratio and a high VT (HVT) cells usage ratio of the IC, and a gate-level circuit power consumption estimation result; and

(3) a third predetermined rule corresponding to the performance exploration: multiple third factors (e.g., multiple parameters, multiple indexes, and/or multiple estimation results) regarding the performance exploration in the multiple synthesis reports should fall within predetermined ranges of the multiple third factors, respectively, for example, the multiple third factors may comprise a clock frequency, one or more timing estimation results and one or more delay estimation results; but the present invention is not limited thereto. According to some embodiments, the multiple predetermined rules such as the first predetermined rule corresponding to the area exploration, the second predetermined rule corresponding to the power exploration and the third predetermined rule corresponding to the performance exploration may vary. In addition, as shown in FIG. 3, the electronic device may execute Steps S102, S103 and S104 subsequently to perform the PPA exploration (e.g., the area exploration, the power exploration and the performance exploration) according to the multiple predetermined rules in a For loop, but the present invention is not limited thereto. According to some embodiments, the type of loop(s) for performing the PPA exploration, the number of loop(s) for performing the PPA exploration, and/or the steps executed in the loop(s) for performing the PPA exploration may vary.

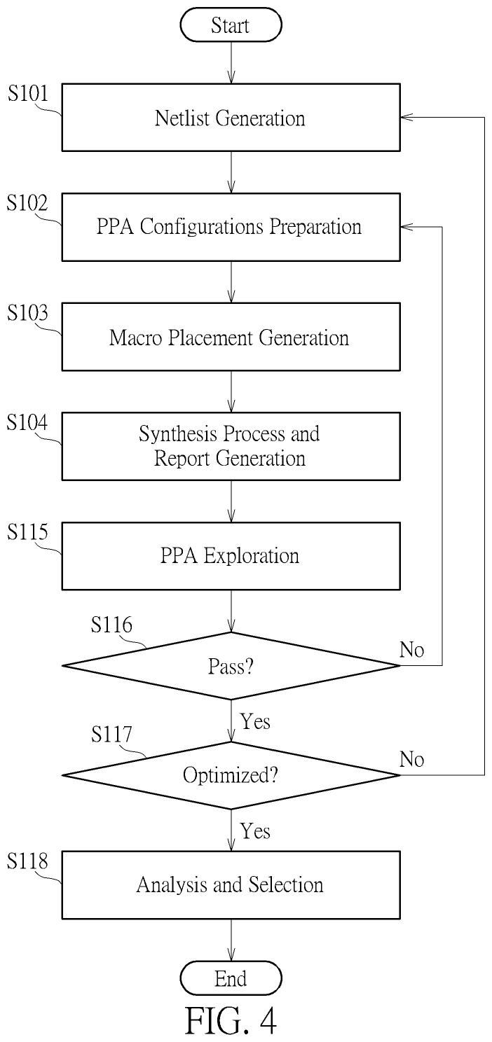

FIG. 4 illustrates a working flow of the synthesis control procedure (e.g., the PFPA tool) corresponding to the ASPR control scheme shown in FIG. 1 according to another embodiment of the present invention. In comparison with the embodiment shown in FIG. 2, Steps S115-S118 may be illustrated to replace Step S105, where the associated partial working flows may vary correspondingly, but the present invention is not limited thereto. Under control of the synthesis control procedure (e.g., the PFPA tool) running on the aforementioned at least one processor, the electronic device may perform the operations of Steps S101-S104 as well as the operations of Steps S115-S118, for performing the ASPR of the target design of the IC product (e.g., the IC). For example, the operations of Steps S101-S104 shown in FIG. 4 may be the same as or similar to the operations of Steps S101-S104 shown in FIG. 2, respectively.

In Step S115, the electronic device may perform the PPA exploration (e.g., the area exploration, the power exploration and the performance exploration) according to the multiple predetermined rules (e.g., the first predetermined rule corresponding to the area exploration, the second predetermined rule corresponding to the power exploration and the third predetermined rule corresponding to the performance exploration).

In Step S116, the electronic device may determine whether any PPA-related configuration among the set of PPA-related configurations passes (e.g., conforms to) the multiple predetermined rules (labeled “Pass” for brevity). If Yes, in a situation where one or more PPA-related configurations among the set of PPA-related configurations pass or conform to the multiple predetermined rules, Step S117 is entered; if No, in a situation where no PPA-related configuration among the set of PPA-related configurations passes or conforms to the multiple predetermined rules, Step S102 is entered, in order to perform the PPA configurations preparation to prepare a new set of PPA-related configurations (e.g., a new set of different shapes and area sizes for the target design).

For example, the new set of PPA-related configurations may be obtained from adjusting the current set of PPA-related configurations (e.g., the latest set of PPA-related configurations prepared in Step S102 when Step S102 is executed for the last time in the working flow shown in FIG. 4) at the time point of executing Step S116, where the electronic device may adjust the current set of PPA-related configurations with at least one predetermined adjustment amount to generate the new set of PPA-related configurations, but the present invention is not limited thereto. For another example, the new set of PPA-related configurations may be obtained from randomly adjusting the current set of PPA-related configurations. According to some embodiments, the electronic device may provide a user interface to allow the user (e.g., the backend integrator) of the synthesis control procedure (e.g., the PFPA tool) to input the aforementioned at least one predetermined adjustment amount into the electronic device in advance, for automatically adjusting the current set of PPA-related configurations with the aforementioned at least one predetermined adjustment amount to generate the new set of PPA-related configurations.

In Step S117, in response to the one or more PPA-related configurations passing or conforming to the multiple predetermined rules, the electronic device may determine whether any PPA-related configuration among the one or more PPA-related configurations is an optimized PPA-related configuration according to at least one predetermined setting (labeled “Optimized” for brevity). If Yes, in a situation where the aforementioned any PPA-related configuration among the one or more PPA-related configurations is an optimized PPA-related configuration, Step S118 is entered; if No, in a situation where no PPA-related configuration among the one or more PPA-related configurations is an optimized PPA-related configuration, Step S101 is entered, in order to perform the netlist generation to generate a new netlist (e.g., a new first netlist such as a new initial netlist) for the target design of the IC. For example, the aforementioned at least one predetermined setting may comprise at least one default setting, but the present invention is not limited thereto. For another example, the aforementioned at least one predetermined setting may comprise at least one user setting of the user (e.g., the backend integrator) of the synthesis control procedure (e.g., the PFPA tool). In some examples, the aforementioned at least one predetermined setting may comprise at least one default setting and/or at least one user setting of the user (e.g., the backend integrator) of the synthesis control procedure (e.g., the PFPA tool).

The new netlist (e.g., the new first netlist such as the new initial netlist) may be obtained from adjusting the current netlist (e.g., the latest first netlist generated in Step S101 when Step S101 is executed for the last time in the working flow shown in FIG. 4) at the time point of executing Step S117, where the electronic device may adjust the current netlist according to at least one predetermined netlist adjustment rule, for example, by performing synthesis recipe adjustment or changing the RTL code (e.g., the Verilog code), in order to generate the new netlist, but the present invention is not limited thereto. For example, the new netlist obtained from randomly adjusting the current netlist. According to some embodiments, the electronic device may provide at least one user interface to allow the user (e.g., the backend integrator) of the synthesis control procedure (e.g., the PFPA tool) to input the aforementioned at least one predetermined netlist adjustment rule into the electronic device in advance, for automatically adjusting the current netlist according to the aforementioned at least one predetermined netlist adjustment rule to generate the new netlist.

In Step S118, the electronic device may perform analysis and selection, and more particularly, complete the PPA exploration (e.g., the area exploration, the power exploration and the performance exploration) to determine at least one PPA-related configuration (e.g., the PPA-related configuration(s) conforming to the aforementioned at least one predetermined setting) among the set of PPA-related configurations (e.g., the latest set of PPA-related configurations prepared in Step S102 when Step S102 is executed for the last time in the working flow shown in FIG. 4) to be the aforementioned at least one optimized PPA-related configuration, select the aforementioned at least one intermediate netlist corresponding to the aforementioned at least one optimized PPA-related configuration from the multiple intermediate netlists, and output the aforementioned at least one intermediate netlist as the aforementioned at least one resultant netlist and at least one floor plan (e.g., one or more floor plans) such as good floor planes, for use of further P&R processing, but the present invention is not limited thereto. According to some embodiments, the electronic device may output the aforementioned at least one resultant netlist and the associated macro placements (e.g., the associated floorplans), for being delivered to the physical designer for further P&R processing.

For better comprehension, the synthesis control procedure may be illustrated with the working flow shown in FIG. 4, but the present invention is not limited thereto. According to some embodiments, one or more steps may be added, deleted, or changed in the working flow shown in FIG. 4. For example, Step S117 and the partial working flow from Step S117 toward Step S101 may be omitted, and Step S118 may be entered in response to the determination result “Yes” of Step S116. More particularly, in Step S116, when determining that the one or more PPA-related configurations pass or conform to the multiple predetermined rules, the electronic device may execute Step S118. For brevity, similar descriptions for these embodiments are not repeated in detail here.

Some implementation details regarding Steps S116 and S117 may be further described as follows. According to some embodiments, the one or more PPA-related configurations passing or conforming to the multiple predetermined rules may comprise at least two PPA-related configurations, and the electronic device may re-enter the partial working flow starting from Step S101 to optimize the set of PPA-related configurations prepared in Step S102, for example, by decreasing the area size in Step S102, but the present invention is not limited thereto. In addition, the multiple predetermined rules may comprise:
(1) in the timing reports, there should be no timing violation, where the electronic device may determine whether any timing violations exists in the timing reports, and more particularly, check whether the Worst Negative Slack (WNS) and the Number of Violating Paths (NVP) fall within the predetermined ranges thereof, respectively, for example, if WNS<−0.1 nanoseconds (ns) and NVP <100, it is determined that no timing violation is found, otherwise, it is determined that at least one timing violation is found;
(2) the congestion hotspot score (e.g., the max number of hotspots) should fall within the predetermined range (e.g., the range below 200) thereof and the congestion overflow ratio (e.g., the Global Routing Cell ratio in the Horizontal direction or the Vertical direction, referred to as “GRC(H/V)” for brevity) should fall within the predetermined range (e.g., the range below 1%) thereof, where the electronic device may determine whether the congestion hotspot score and the congestion overflow ratio fall within the predetermined ranges thereof, respectively, for example, if GRC(H/V)<1% and the max number of hotspots is less than 200, it is determined that the congestion hotspot score and the congestion overflow ratio fall within the predetermined ranges thereof, respectively, otherwise, it is determined that the congestion hotspot score and the congestion overflow ratio fail to completely fall within the predetermined ranges thereof, respectively;
(3) in the cell threshold voltage (VT) usage reports, the ultra-low threshold voltage (ULVT) cell usage rate should fall within the predetermined range (e.g., the range below 10%) thereof, in order to meet the low power quality, for example, if the ULVT cell usage rate is less than 10%, the electronic device may determine that the ULVT cell usage rate falls within the predetermined range thereof, otherwise, the electronic device may determine that the ULVT cell usage rate fails to fall within the predetermined range thereof; and
(4) in the cell area reports, the target standard cell utilization rate (U-rate) should fall within the predetermined range (e.g., the range below 70%) thereof, for example, if the U-rate is less than 70%, the electronic device may determine that the U-rate falls within the predetermined range thereof, otherwise, the electronic device may determine that the U-rate fails to fall within the predetermined range thereof;
but the present invention is not limited thereto. For brevity, similar descriptions for these embodiments are not repeated in detail here.

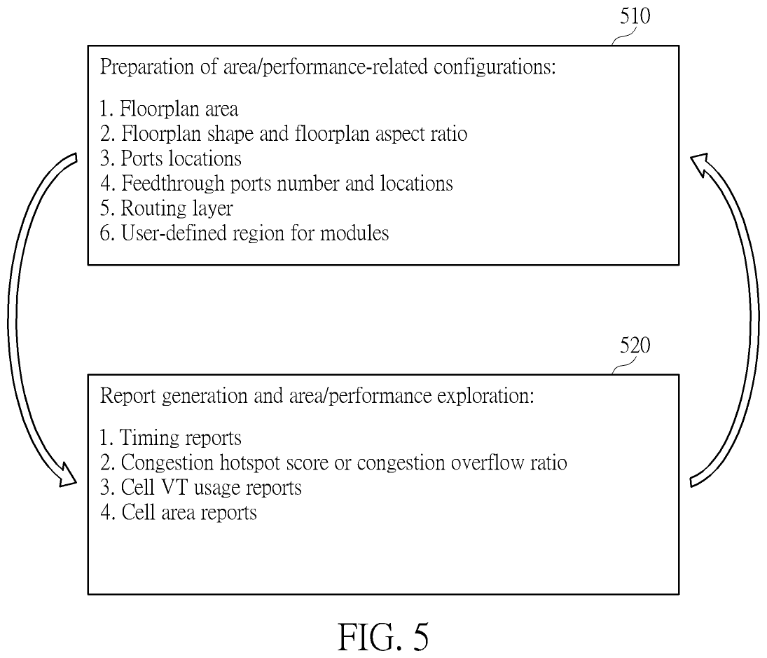

FIG. 5 illustrates some implementation details regarding the area exploration and the performance exploration of the loop-based control scheme shown in FIG. 3 according to an embodiment of the present invention. The electronic device may perform the area exploration and the performance exploration in an iterative manner, and more particularly, perform the area/performance-related configurations preparation 510 in the PPA configurations preparation mentioned in Step S102 to prepare a set of area/performance-related configurations among the set of PPA-related configurations generated in Step S102 (labeled “Preparation of area/performance-related configurations” for brevity), and perform the report generation and area/performance exploration 520 with respect to the set of area/performance-related configurations to generate a set of area/performance-related synthesis reports of the multiple intermediate netlists for the set of area/performance-related configurations among the multiple synthesis reports generated in Step S104, for analyzing the set of area/performance-related synthesis reports, in order to complete the area exploration and the performance exploration. For example, the set of area/performance-related configurations may comprise:
(1) the floorplan area;
(2) the floorplan shape and the floorplan aspect ratio;
(3) the ports locations;
(4) the feedthrough ports number and locations;
(5) the routing layer; and
(6) the user-defined region for modules;

but the present invention is not limited thereto. According to some embodiments, the set of area/performance-related configurations may vary. In addition, the set of area/performance-related synthesis reports may comprise:
(1) the timing reports of one or more parts of the IC, where the timing reports may comprise the timing estimation results, the delay estimation results, the slacks of the timing paths, etc. of the one or more parts of the IC, where the electronic device may refer to the slacks of the timing paths in the timing reports to determine whether the PPA configurations of this time would cause a timing risk;
(2) the congestion report of the IC, where the congestion report may comprise one or more congestion hotspot scores and/or one or more congestion overflow ratios of the IC;
(3) the cell VT usage reports of one or more VT types of cells within the IC, where the cell VT usage reports may comprise one or more cell VT usage ratios of the one or more VT types of cells within the IC; and
(4) the cell area reports of one or more types of cells within the IC, where the cell area reports may comprise one or more cell areas of the one or more types of cells within the IC, as well as the total logical area thereof, where the electronic device may refer to the total logical area in the cell area reports to determine whether the PPA configurations of this time are acceptable, and more particularly, determine whether the PPA configurations of this time are acceptable according to whether the increment (or the increase ratio thereof) of the total logical area is within a predetermined value;
but the present invention is not limited thereto. According to some embodiments, the set of area/performance-related synthesis reports may vary.

According to some embodiments, the multiple first factors regarding the area exploration in the multiple synthesis reports may comprise the timing estimation results, the delay estimation results, etc. in the timing reports, the one or more congestion hotspot scores and/or one or more congestion overflow ratios in the congestion report, the one or more cell VT usage ratios in the cell VT usage reports, and the one or more cell areas in the cell area reports. In addition, the multiple third factors regarding the performance exploration in the multiple synthesis reports may comprise the timing estimation results, the delay estimation results, etc. in the timing reports, but the present invention is not limited thereto. For brevity, similar descriptions for these embodiments are not repeated in detail here.

According to some embodiments, the set of area/performance-related synthesis reports may further comprise a clock frequency report of one or more clocks of the IC, where the clock frequency report may comprise one or more clock frequencies of the one or more clocks of the IC. For example, the multiple third factors regarding the performance exploration in the multiple synthesis reports may further comprise the one or more clock frequencies in the clock frequency report. For brevity, similar descriptions for these embodiments are not repeated in detail here.

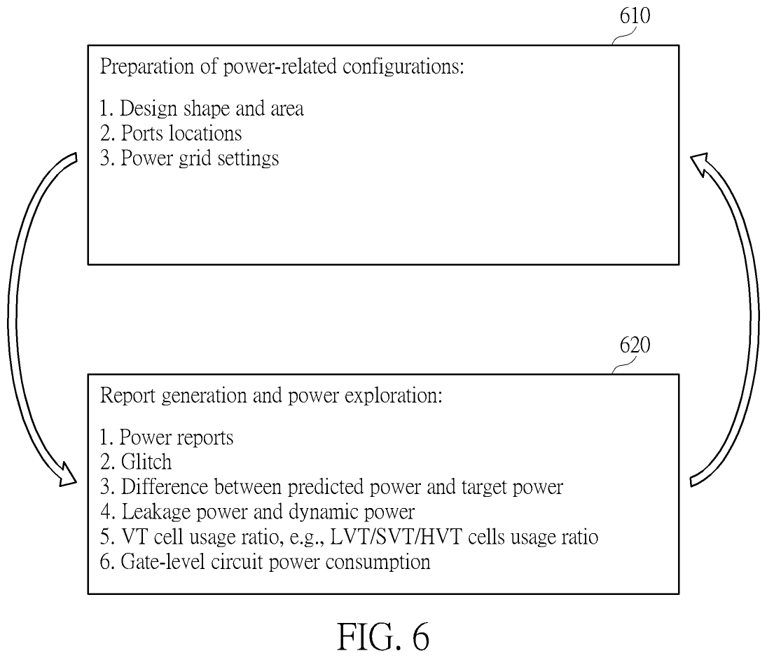

FIG. 6 illustrates some implementation details regarding the power exploration of the loop-based control scheme shown in FIG. 3 according to an embodiment of the present invention. The electronic device may perform the power exploration in an iterative manner, and more particularly, perform the power-related configurations preparation 610 in the PPA configurations preparation mentioned in Step S102 to prepare a set of power-related configurations among the set of PPA-related configurations generated in Step S102 (labeled “Preparation of power-related configurations” for brevity), and perform the report generation and power exploration 620 with respect to the set of power-related configurations to generate a set of power-related synthesis reports of the multiple intermediate netlists for the set of power-related configurations among the multiple synthesis reports generated in Step S104, for analyzing the set of power-related synthesis reports, in order to complete the power exploration. For example, the set of power-related configurations may comprise:
(1) the design shape and area;
(2) the ports locations; and
(3) the power grid settings;
but the present invention is not limited thereto. According to some embodiments, the set of power-related configurations may vary. In addition, the set of power-related synthesis reports may comprise:
(1) the power reports of one or more parts of the IC, where the power reports may comprise the power estimation results of the one or more parts of the IC;
(2) the glitch reports of one or more parts of the IC, where the glitch reports may comprise the glitch estimation results of the one or more parts of the IC;
(3) the power difference report of the IC, where the power difference report may comprise the difference between the predicted power of the IC and the target power of the IC;
(4) the leakage/dynamic power report of the IC, where the leakage/dynamic power report may comprise the leakage power and the dynamic power of the IC;
(5) the VT cell usage ratio report of the IC, where the VT cell usage ratio report may comprise the VT cell usage ratio(s) of the IC, such as the LVT cells usage ratio, the SVT cells usage ratio and the HVT cells usage ratio of the IC; and
(6) the gate-level power consumption report of one or more gate-level circuits within the IC, where the gate-level power consumption report may comprise the gate-level circuit power consumption such as the gate-level circuit power consumption estimation results of the one or more gate-level circuits within the IC;
but the present invention is not limited thereto. According to some embodiments, the set of power-related synthesis reports may vary.

According to some embodiments, the multiple second factors regarding the power exploration in the multiple synthesis reports may comprise the power estimation results in the power reports, the glitch estimation results in the glitch reports, the difference between the predicted power and the target power in the power difference report, the leakage power and the dynamic power in the leakage/dynamic power report, the VT cell usage ratio(s) (e.g., the LVT cells usage ratio, the SVT cells usage ratio and the HVT cells usage ratio) in the VT cell usage ratio report, and the gate-level circuit power consumption such as the gate-level circuit power consumption estimation results in the gate-level power consumption report. For brevity, similar descriptions for these embodiments are not repeated in detail here.

Regarding the power exploration and the associated power estimation, some details may be further described as follows. When adopting the non-ASPR control scheme shown in the upper half part of FIG. 1, the multiple IC design teams may be unaware of incorrect power setting(s) until a very late time point in the P&R processing, and therefore need to redo the entire P&R and synthesis work, which may cause great damage to the IC design process. Conversely, when adopting the ASPR control scheme shown in the lower half part of FIG. 1, the multiple IC design teams may be aware of any incorrect power setting at a very early time point during the preliminary real synthesis done by the backend integrator with the aid of the PFPA tool, and therefore, the power-related issues can be evaluated and resolved early in IC design. According to some embodiments, the requirements at the project implementation level may define the design shape and area. When conducting low-power design, the design shape and area need to be determined according to the implementation requirements of the project. This involves determining the size and shape of the circuit board or wafer, and determining the area designed within a specific space, in order to ensure that the design can comply with the space constraints and requirements of the actual application. In addition, selecting the location of expected installed ports can ensure the convenience and effectiveness of the design regarding connection and interaction. This is helpful on determining the configuration and settings of the power grid to ensure the correct supply of power and ground signals. Regarding the power grid settings, the power grid may be a network used for distributing power and ground signals. In low-power designs, the configuration and settings of the power grid are crucial. It is needed to ensure that the power and ground signals are transmitted efficiently throughout the design to support correct circuit operations and data transfer. The power grid settings may comprise the connection points of power and ground, the number and width(s) of connection lines, the location of buffers, etc., and may be configured according to the power consumption needs and timing requirements of the design to ensure the stability and reliability of the power and ground.

For example, based on the first netlist generated in Step S101 and the set of PPA-related configurations (e.g., the design shape setting) prepared in Step S102, the electronic device may generate the set of macro placements macro placement by using or calling a macro placement subroutine (e.g., an automatic macro placement tool) running on the in Step S103. The electronic device may perform the macro placement generation to generate the multiple sets of macro placements respectively corresponding to the set of PPA-related configurations in Step S103, execute the synthesis processing according to the multiple sets of macro placements together with the RTL code and execute the clock tree synthesis and the Synopsys PrimeTime PX Power Analysis (which may be referred to as “PTPX” for brevity) to obtain the associated power analysis reports (e.g., the PTPX reports) among the multiple synthesis reports in Step S104, and analysis the PTPX reports and take appropriate actions while performing the PPA exploration (e.g., the power exploration) mentioned in Step S115, and more particularly, adjust the power grid setting, adjust the shape and area (even the whole chip floorplan) and modify the RTL code, but the present invention is not limited thereto.

In order to calculate the IR impact such as the IR drop (e.g., the voltage drop V, or the potential difference, between two ends of a conducting wire with the resistance R when the current I is flowing therethrough; according to Ohm's law: V=(I*R)) based on the estimated power, it may be helpful to use the following approach:
(1) adjusting the power grid settings: as the power grid may be regarded as the network used for distributing power and ground signals in the target design, the electronic device operating according to the method may be arranged to adjust the settings of the power grid according to the estimated power consumption in order to ensure that the power and ground can meet the demand, for example, the electronic device may adjust the connection points for power and ground, and increase the number(s) or the width(s) of connection lines for power and ground; and
(2) glitch elimination low power design: as the glitch may refer to a transient phenomenon caused by timing problems or inconsistent signal transmission delays in digital circuits, in low-power designs, the electronic device operating according to the method may be arranged to adopt some design circuit methods to reduce or eliminate the glitch in order to reduce the power consumption; but the present invention is not limited thereto. Regarding the aforementioned IR impact such as the IR drop, it is an important factor to be considered in electronic circuit design and analysis. When the current flows through a circuit, the resistance causes a voltage drop, which may have an impact on the performance of the circuit. Especially in large integrated circuits or high-speed electronic systems, the management and reduction of IR drop is very important, for ensuring stable operation and reliability of the circuit. In addition, the electronic device operating according to the method may optimize the leakage power and the dynamic power according to the estimated difference between power and power target, for example, by adopting the following methods:
(1) switching activity interchange format (SAIF)-based synthesis: as SAIF may be regarded as a format used for describing signal switching behavior and may provide the amount of switching activity of a signal at different time points, in the SAIF-based synthesis, the electronic device operating according to the method may be arranged to perform synthesis according to the switching activity of the signals in order to optimize the power consumption of the gate-level circuit, where by analyzing the switching activity of the signals, the electronic device may select appropriate gate-levels for different signals to reduce the power consumption; and
(2) determining and review the VT cell usage ratio(s) to modify the target design correspondingly: in low-power design, the electronic device operating according to the method may be arranged to evaluate and modify the usage ratios of different types of VT cells within the IC according to the power consumption target since different types of VT cells may have different power consumption and performance characteristics, where by evaluating the usage ratios of different types of VT cells (or VT units), the electronic device may select appropriate VT cells (or VT units) to optimize the power consumption of the gate-level circuit, and more particularly, modify the target design, for example, by replacing the VT unit, adjusting the logic structure, etc., in order to achieve the goal of power consumption optimization. For brevity, similar descriptions for these embodiments are not repeated in detail here.

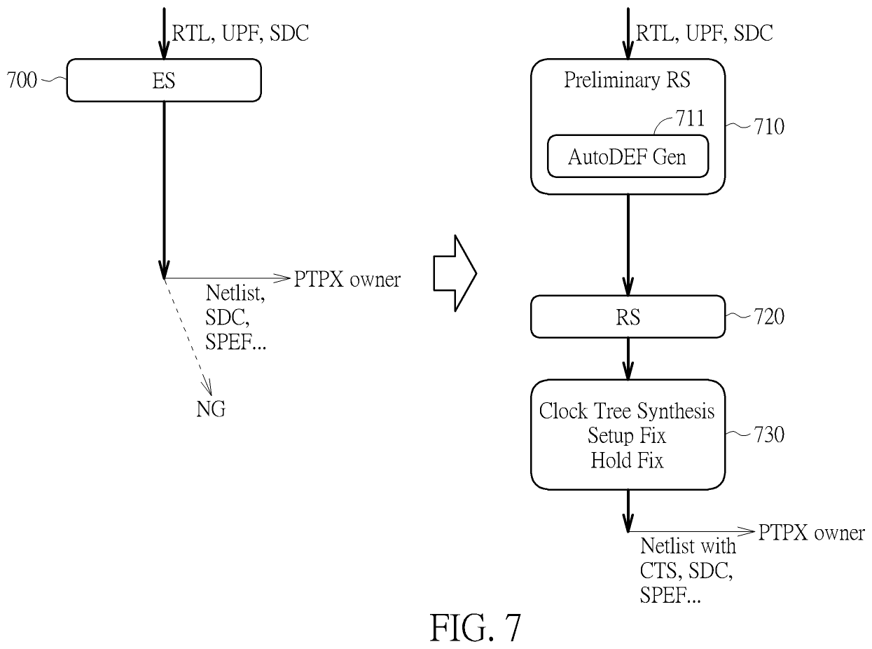

FIG. 7 illustrates, in the right half part thereof, an ASPR-based power estimation control scheme of the method according to an embodiment of the present invention, where a non-ASPR-based power estimation control scheme may be illustrated in the left half part of FIG. 7 for better comprehension. The ES 700 shown in FIG. 7 may be the same as or similar to the early synthesis (ES) in the non-ASPR control scheme shown in the upper half part of FIG. 1, the Preliminary RS 710 shown in FIG. 7 may be the same as or similar to the preliminary real synthesis (RS) in the ASPR control scheme shown in the lower half part of FIG. 1, and the RS 720 shown in FIG. 7 may be the same as or similar to the real synthesis (RS) in the ASPR control scheme shown in the lower half part of FIG. 1, where the automatic DEF netlist generation 711 (labeled “AutoDEF Gen” for brevity) may be the same as or similar to the operation of generating and outputting the netlist of the design exchange format (DEF) in the ASPR control scheme shown in the lower half part of FIG. 1, but the present invention is not limited thereto. According to some embodiments, the ES 700, the Preliminary RS 710 and/or the RS 720 shown in FIG. 7 may vary.

According to the non-ASPR-based power estimation control scheme shown in the left half part of FIG. 7, the backend integrator may take over the RTL code, a unified power format (UPF) code and a Synopsys Design Constraints (SDC) code (respectively labeled “RTL”, “UPF” and “SDC” for brevity) and do the ES 700, and perform non-ASPR-based power estimation during the ES 700, in order to deliver the netlist as well as the associated SDC and Standard Parasitic Exchange Format (SPEF) codes to the PTPX owner. As a result of the lack of physical location information in the ES 700, it is typically that the power estimation result is not good (labeled “NG” for brevity).

According to the ASPR-based power estimation control scheme shown in the right half part of FIG. 7, the backend integrator may take over the RTL code, the UPF code and the SDC code (respectively labeled “RTL”, “UPF” and “SDC” for brevity) and do the Preliminary RS 710 with the aid of the PFPA tool, and perform ASPR-based power estimation during the Preliminary RS 710, and may further perform additional ASPR-based power estimation such as the operations 730 of the clock tree synthesis, the setup fix and the hold fix, in order to deliver the netlist as well as the associated Clock Tree Synthesis (CTS), SDC and SPEF codes to the PTPX owner. Please note that the backend integrator may be able to do real RS PPA assessment and recipe fine-tuning earlier by using the PFPA tool, allowing efficient exploration and assessment of PPA-related configurations in synthesis and APR for IC design. Regarding the SPEF codes, SPEF is a standardized file format used for describing parasitic parameters in an IC's physical design, such as capacitance, resistance, and delay. SPEF files with the SPEF codes usually contain important information such as the electrical characteristics and connection relationships between various components in the IC physical design, which are very important for subsequent simulation, verification and layout. The SPEF files can be used in various tools such as SPICE simulation, timing analysis, power consumption analysis, etc. to ensure the accuracy and reliability of the design. In addition, the CTS is an important step in the IC design flow, used for designing and implementing clock systems to ensure correct timing of the entire circuit. For brevity, similar descriptions for this embodiment are not repeated in detail here.

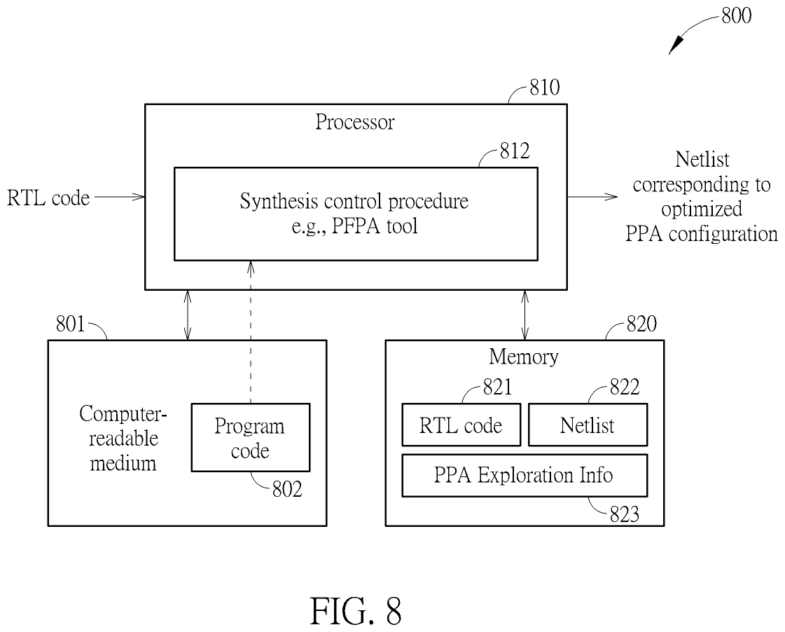

FIG. 8 illustrates an electronic device 800 that operates according to the method according to an embodiment of the present invention, where a computer-readable medium 801 storing a program code 802 related to the method may be illustrated in the lower left part of FIG. 8 for better comprehension. The electronic device 800 may comprise the computer-readable medium 801, at least one processor (e.g., one or more processors), which may be collectively referred to as the processor 810, and a memory 820. For better comprehension, the electronic device 800, the computer-readable medium 801, the program code 802, the processor 810 and a synthesis control procedure 812 running on the processor 810 may be taken as examples of the aforementioned electronic device that operates according to the method, the aforementioned computer-readable medium, the aforementioned program code, the aforementioned at least one processor within the aforementioned electronic device and the synthesis control procedure corresponding to the ASPR control scheme shown in FIG. 1, respectively, but the present invention is not limited thereto. In the architecture shown in FIG. 8, the computer-readable medium 801 may be implemented by way of a hard disk drive (HDD), a solid state drive (SSD), a non-volatile memory such as a Flash memory, etc., and the memory 820 may be implemented by way of a volatile memory such as a random access memory (RAM), but the present invention is not limited thereto.

In addition, the electronic device 800 may load the program code 802 from the computer-readable medium 801 onto the processor 810 to be the synthesis control procedure 812 (e.g., the PFPA tool) running on the processor 810. Under control of the synthesis control procedure 812 (e.g., the PFPA tool) running on the processor 810, the electronic device 800 may perform the operations of Steps S101-S105 in the working flow shown in FIG. 2 or the operations of Steps S101-S104 and S115-S118 in the working flow shown in FIG. 4, for performing the ASPR of the target design of the IC product (e.g., the IC), and more particularly, receive the RTL code generated in the initial design phase, such as the RTL code written by the designer engineer, and temporarily store the RTL code into the memory 820 to be the RTL code 821 (e.g., the temporarily stored or buffered RTL code) for further use during the preliminary real synthesis, perform the synthesis and P&R processing to generate the multiple intermediate netlists such as the netlists 822 and generate the multiple synthesis reports to be the PPA exploration information (Info) 823 for performing the PPA exploration, and complete the ASPR of the target design of the IC product (e.g., the IC) to generate and output the aforementioned at least one intermediate netlist corresponding to the aforementioned at least one optimized PPA-related configuration to be the aforementioned at least one resultant netlist, for use of further P&R processing. For brevity, similar descriptions for this embodiment are not repeated in detail here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for performing block level exploration of integrated circuit (IC) design, the method being applied to an electronic device, the method comprising:
running a synthesis control procedure on at least one processor within the electronic device, for performing automatic synthesis plus place and route (ASPR) of a target design of an IC, wherein the synthesis control procedure comprises:
performing netlist generation to generate a first netlist for the target design of the IC;
performing performance, power and area (PPA) configurations preparation to prepare a set of PPA-related configurations;
performing macro placement generation to generate a set of macro placements corresponding to the set of PPA-related configurations; and
executing synthesis processing according to the set of macro placements to generate multiple intermediate netlists, respectively, and generating multiple synthesis reports of the multiple intermediate netlists for the set of PPA-related configurations, respectively, for selectively outputting at least one intermediate netlist among the multiple intermediate netlists as at least one resultant netlist and at least one floor plan, for use of further place and route (P&R) processing.

2. The method of claim 1, wherein performing the netlist generation to generate the first netlist for the target design of the IC further comprises:
executing synthesis processing without referring to any predetermined physical location information regarding any part of the IC, to generate the first netlist for the target design of the IC.

3. The method of claim 1, wherein performing the netlist generation to generate the first netlist for the target design of the IC further comprises:
receiving a register transfer level (RTL) code, wherein the RTL code indicates the target design of the IC; and
executing synthesis processing according to the RTL code to generate the first netlist for the target design of the IC.

4. The method of claim 1, wherein the set of PPA-related configurations comprise at least one performance-related configuration, at least one power-related configuration and at least one area-related configuration.

5. The method of claim 4, wherein the at least one area-related configuration comprises at least one configuration of at least one area for being occupied by at least one predetermined component within the IC.

6. The method of claim 5, wherein the at least one configuration of the at least one area comprises at least one configuration of one or a combination of a shape of the at least one area, an area size of the at least one area, and an aspect ratio of the at least one area.

7. The method of claim 5, wherein the at least one area-related configuration further comprises at least one configuration of one or a combination of a port location of at least one port within the IC, a feedthrough port number of at least one feedthrough port within the IC, a feedthrough port location of the at least one feedthrough port, at least one routing layer within the IC, and a user-defined region for at least one module within the IC.

8. The method of claim 4, wherein the at least one performance-related configuration comprises at least one configuration of at least one area for being occupied by at least one predetermined component within the IC.

9. The method of claim 8, wherein the at least one configuration of the at least one area comprises at least one configuration of one or a combination of a shape of the at least one area, an area size of the at least one area, and an aspect ratio of the at least one area.

10. The method of claim 8, wherein the at least one performance-related configuration further comprises at least one configuration of one or a combination of a port location of at least one port within the IC, a feedthrough port number of at least one feedthrough port within the IC, a feedthrough port location of the at least one feedthrough port, at least one routing layer within the IC, and a user-defined region for at least one module within the IC.

11. The method of claim 4, wherein the at least one power-related configuration comprises at least one configuration of at least one area for being occupied by at least one predetermined component within the IC.

12. The method of claim 11, wherein the at least one configuration of the at least one area comprises at least one configuration of one or a combination of a shape of the at least one area, an area size of the at least one area, and an aspect ratio of the at least one area.

13. The method of claim 11, wherein the at least one power-related configuration further comprises at least one configuration of one or a combination of a port location of at least one port within the IC, and a power grid setting of at least one power grid line within the IC.

14. The method of claim 1, wherein the set of PPA-related configurations comprise at least one configuration of at least one area for being occupied by at least one predetermined component within the IC; and performing the macro placement generation to generate the set of macro placements corresponding to the set of PPA-related configurations further comprises:
performing the macro placement generation to generate the set of macro placements corresponding to the set of PPA-related configurations for placing the at least one predetermined component.

15. The method of claim 14, wherein the at least one configuration of the at least one area comprises at least one configuration of one or a combination of a shape of the at least one area, an area size of the at least one area, and an aspect ratio of the at least one area.

16. The electronic device that operates according to the method of claim 1, wherein the electronic device is arranged to selectively output the at least one intermediate netlist among the multiple intermediate netlists as the at least one resultant netlist, for use of further P&R processing.

17. A computer-readable medium storing a program code which causes the electronic device to operate according to the method of claim 1 when executed by the at least one processor.
